(19) United States
(12) Patent Application Publication
(10) Pub. No.: US 2016/0035563 A1
(43) Pub. Date: Feb. 4, 2016

(54) APPARATUS AND METHOD FOR PROCESSING SEMICONDUCTOR WAFERS

(71) Applicant: TAIWAN SEMICONDUCTOR MANUFACTURING COMPANY LTD., Hsinchu (TW)

(72) Inventors: TZU-KEN LIN, TAICHUNG CITY (TW); YUNG CHING CHEN, TAICHUNG COUNTY (TW); I-CHANG WU, TAICHUNG CITY (TW); CHAO-TZUNG TSAI, TAICHUNG CITY (TW); CHING-LUN LAI, TAICHUNG CITY (TW)

(21) Appl. No.: 14/449,911

(22) Filed: Aug. 1, 2014

(51) Int. Cl. H01L 21/02; H01J 37/32; B08B 5/02; B08B 5/04; H01L 21/67; H01L 21/677

(52) U.S. Cl. CPC H01L 21/02057; H01L 21/67017; H01L 21/67201; H01L 21/67253; H01L 21/67742; H01L 21/67207; B08B 5/02; B08B 5/04; H01J 37/32853; H01J 37/32899

(57) ABSTRACT

An apparatus for processing a semiconductor wafer includes a factory interface configured to couple with a manufacturing chamber. The factory interface includes a robot; an orienter adjacent to the robot; and a particle remover above the orienter and facing toward a wafer. The particle remover is configured to blow ionized gas on a surface of the wafer so as to remove particles.

### FIELD

The present disclosure relates to processes used to fabricate semiconductor devices, and more specifically to an apparatus used to remove particles equipped in a semiconductor fabrication tool.

### BACKGROUND

The fabrication of semiconductor devices includes hundreds of individual steps performed on a wafer. For example, the steps of this process can include oxidation, diffusion, ion implantation, thin film deposition, cleaning, etching and lithography. Processing chambers for such steps have been designed as multiple processing stations or modules, wherein the processing chambers are arranged in a radial arrangement around a central handling mechanism and are designed to perform a certain type of processing operation.

However, a yield of semiconductor devices can be adversely influenced by the patterning procedure, such as photolithography and a dry etching, due to the presence of unwanted particles present in the processing chambers. The particles in the processing chambers, formed from previous dry etching procedures or depositions, can settle on an exposed region of metal layers or exposed photoresist layers. The particles mask the exposed region during a dry etching procedure, resulting in damages on a predetermined pattern and leading to an unwanted pattern. Thus, removing the particles is of great importance for the fabrication of semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a top view illustrating a multi-chamber system in accordance with some embodiments of the present disclosure.

FIG. 2 is a top view illustrating a multi-chamber system in accordance with some embodiments of the present disclosure.

FIG. 3 is a flow chart of a particle removing process in accordance with some embodiments of the present disclosure.

FIG. 4 is a top view illustrating a multi-chamber system in accordance with some embodiments of the present disclosure.

FIG. 5 is a flow chart of a particle removing process in accordance with some embodiments of the present disclosure.

FIG. 6 is a flow chart of a particle removing process in accordance with some embodiments of the present disclosure.

FIG. 7 is an illustration of a configuration of particle removers in accordance with some embodiments of the present disclosure.

FIGS. 8A-8B are schematic diagrams illustrating the particle remover in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “wafer” and “substrate,” as used herein, are to be understood as including silicon, silicon-on-insulator (SOI) technology, silicon-on-sapphire (SOS) technology, doped and undoped semiconductors, epitaxial layers of silicon supported by a base semiconductor foundation, and other semiconductor structures. Furthermore, when reference is made to a “wafer” or “substrate” in the following description, previous processing steps may have been utilized to form regions, junctions, or material layers in or over the base semiconductor structure or foundation. In addition, the semiconductor does not need to be silicon-based, but could be based on silicon-germanium, germanium, gallium arsenide or other semiconductor structures.

The terms “deposition” and “deposit,” as used herein, refer to operations of depositing materials on a substrate using a vapor phase of a material to be deposited, a precursor of the material, and an electrochemical reaction or sputtering/reactive sputtering. Depositions using a vapor phase of a material include any operations such as, but not limited to, chemical vapor deposition (CVD) and physical vapor deposition (PVD). Examples of vapor deposition methods include hot filament CVD, rf-CVD, laser CVD (LCVD), conformal diamond coating operations, metal-organic CVD (MOCVD), thermal evaporation PVD, ionized metal PVD (IMPVD), electron beam PVD (EBPVD), reactive PVD, atomic layer deposition (ALD), plasma enhanced CVD (PECVD), high density plasma CVD (HDPCVD), low pressure CVD (LPCVD), and the like. Examples of deposition using an electrochemical reaction include electroplating, electro-less plating, and the like. Other examples of deposition include pulse laser deposition (PLD) and atomic layer deposition (ALD).

The fabrication of microelectronic devices involves a complicated process sequence including hundreds of process steps performed on semiconductor substrates. For example, such process steps include cleaning, oxidation, diffusion, ion implantation, thin film deposition, etching and lithography. By using lithography and etching processes, a predetermined pattern is transferred to a material layer or a substrate. In the lithography step, a blanket photoresist layer is exposed to a radiation source through a reticle or photomask containing a pattern so that an image of the pattern is formed in the photoresist layer. By developing the photoresist layer in a suitable chemical solution, portions of the photoresist layer are removed, thus resulting in a patterned photoresist layer. Later, subsequent etching processes are performed to etch portions of an underlying material layer uncovered by the patterned photoresist layer. With the patterned photoresist layer acting as a mask, the uncovered portions of the underlying material layer are exposed to a reactive environment, e.g., using a wet or dry etching, which results in the pattern being transferred to the underlying material layer. The lithography and etching processes are essential steps to determine scales of the microelectronic devices.

The results of the lithography and etching processes affect a product yield of the microelectronic devices. Defects are very important indicators that affect the product yield rate. The product yield of microelectronic devices can be adversely influenced by the lithography and etching processes, due to the presence of unwanted particles present in the manufacturing chamber. It is found that particles attached on a wafer cause serious defects during a lithography or etching process. The particles may appear during transport or after any function process. When the particles fall on a front side of the wafer, devices or interconnects under the particles will become defective after the etching process. The particles may shield the patterned photoresist layer and hinder the etching gas from reacting with the underlying material layer, thus resulting in a partial etching after the etching process. When the particles attach or settle on a back side of the wafer or an electrostatic chuck (ESC), it will trigger a back side helium alarm. Specifically, the particles may settle on the electrostatic chuck (ESC) or a back side of the wafer. This in turn results in a poor contact between the wafer and the ESC. Since the wafer cannot sit flush on the ESC, this allows helium to leak from the poor contact position or a gap between the wafer and the ESC, resulting in the monitoring of helium in the dry etch chamber, and permits particle contamination in the dry etching tool. If the helium alarm is triggered, the manufacturing process shall be shut down. The manufacturing chambers or the wafer shall be cleaned and reloaded. Concerning the particle issues, an atmosphere transfer module (ATM) or a vacuum transfer module (VTM) Robot station has no devices for removing particles. The wafers can become subjected to particle contamination as a result of the above-mentioned conditions during transportation or any manufacturing process. In order to solve the problem of the particles in a manufacturing process, the present disclosure provides a structure of a particle remover and a configuration of the particle remover equipped in a factory interface or a manufacturing chamber.

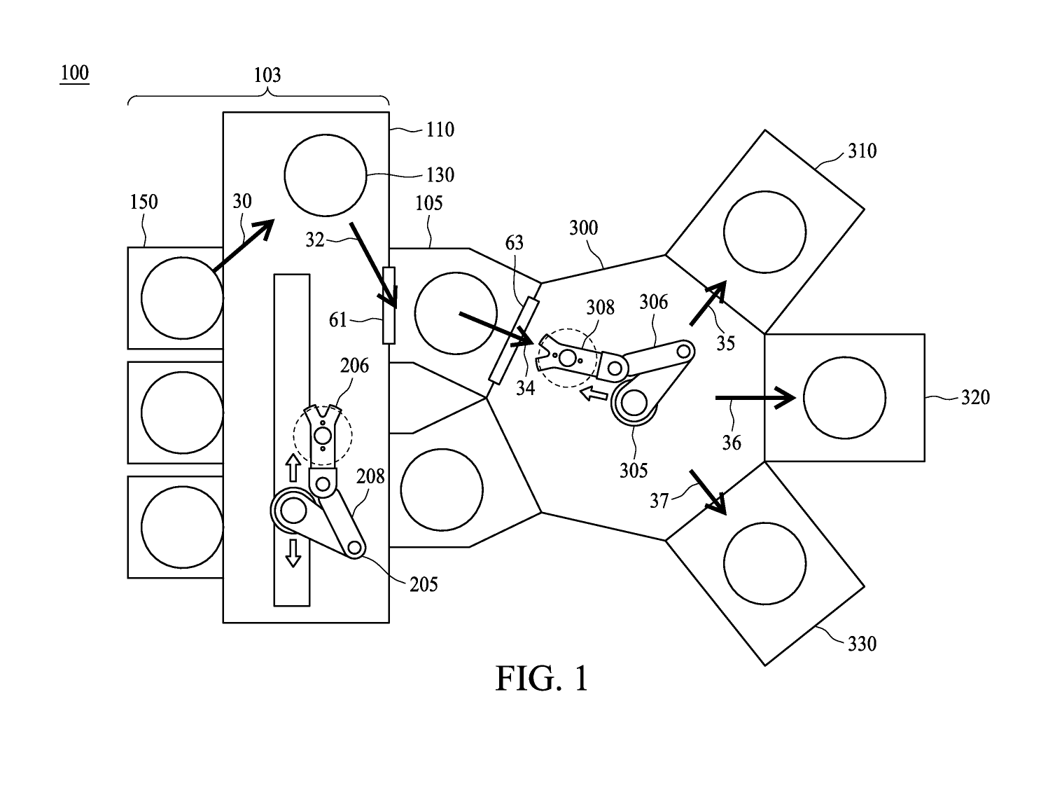

In reference to the figures, FIG. 1 is a top view illustrating a multi-chamber system 100 in accordance with some embodiments of the present disclosure. The multi-chamber system 100 includes a factory interface 103 and a buffer chamber 300. The factory interface 103 and the buffer chamber 300 are connected by load lock chamber 105. The multi-chamber system 100 has several process chambers disposed around the buffer chamber 300. The buffer chamber 300 is coupled to a vacuum system (not shown) so as to provide a reduced atmosphere condition.

The factory interface 103 is configured to load and transfer wafers to a manufacturing chamber. The factory interface 103 is also configured to couple with a manufacturing chamber, for example, load lock chamber 105. The factory interface 103 includes a robot 205, an orienter 130, a housing 110 and a load port 150. The housing 110 is designed to operate in a first environment; for example, the housing 110 is filled with a non-active gas such as nitrogen or argon. In an embodiment, the housing 110 is kept at room temperature and a room pressure, which refers to an atmosphere transfer module (ATM). Do note that the first environment of the housing 110 has many possible variations and options.

A wafer or a cassette of wafers is introduced into the housing 110 through the load port 150, which is often referred to as a load-station for loading and unloading the wafers. For loading wafers, a cassette is put in the load port 150 by a machine (not shown) or a human. At this moment, the load port 150 is temporally in an atmosphere environment. A valve (not shown) between the housing 110 and the load port 150 is closed. As the load port 150 is turned to the first environment, the valve is opened and allows the robot 205 to pass through. A wafer is handled by the robot 205 and transferred to the housing 110.

The robot 205, equipped within the housing 110, transfers the wafer from the load port 150 to an orienter 130. The robot 205 is movable/controllable in at least three-axes or rotatable at any angles. The robot 205 is a single-blade robot, which has a robot blade 206 attached to a robot arm 208. The robot blade 206 is adapted for handling and transferring a wafer to and from various positions.

An orienter 130 is located adjacent to the robot 205 so that the robot 205 is able to transfer wafers to the orienter 130. Later, the wafer is transferred to an orienter 130 by the robot 205 shown as an arrow 30. The orienter 130 is configured to adjust the wafer to a correct orientation for the next manufacturing process. The orienter 130 is able to rotate the wafer and adjust an orientation of the wafer so as to allow an incident optical beam to be directed to a test pattern or a dock on the wafer and return the optical beam in order to be detected by the orienter 130. With the orienter 130, the wafer is precisely positioned and ready to etch or deposit.

The wafer is then transferred from the orienter 130 to load lock chamber 105 by the robot 205 shown as an arrow 32. A valve 61 between the housing 110 and the load lock chamber 105 is opened and allows the robot 205 to pass through and place the wafer in position. When the valve 61 is closed, the load lock chamber 105 is vacuumed to a second environment; for example, the load lock chamber 105 is maintained at a low pressure such as about 200 m-torrs. Other pressures may also be used, for example, less than about 1 torr, with a lower pressure limit of about 10 m-torrs, as determined by the type of vacuum pump used for evacuation of the load lock chamber 105.

Prior to vacuuming the load lock chamber 105, the buffer chamber 300 is already maintained as the second environment so that environments of the load lock chamber 105 and the buffer chamber 300 are substantially equal. The buffer chamber 300 is usually kept in a vacuum environment so as to avoid particle contamination. After the load lock chamber 105 is vacuumed to the second environment, a valve 63 between the load lock chamber 105 and the buffer chamber 300 is opened. The wafer is then handled by a robot 305 and transferred from the load lock chamber 105 to the buffer chamber 300 shown as an arrow 34. The robot 305 is similar to the robot 205 and is also configured to transfer a wafer to a manufacturing chamber. The robot 305 includes a robot arm 306 and a robot blade 308. In an embodiment, the robot arm 306 is equipped as dual-arms or a single arm. Further, the buffer chamber 300 is coupled with a plasma process chamber 310, a deposition chamber 320 and a diffusion chamber 330. The plasma process chamber 310 is able to operate a dry etching process including, for example, a reactive ion etching process. The plasma process chamber 310 provides reactive ion gas so as to react with material layers or the wafer. The deposition chamber 320 provides a vapor phase of a material including any operations such as, but not limited to, chemical vapor deposition (CVD) and physical vapor deposition (PVD). A material layer can be deposited on the wafer in the deposition chamber 320. The diffusion chamber 330 provides a thermal process such as a rapid thermal annealing or a laser annealing. A deposited layer can be annealed in the diffusion chamber 330. The wafer is then transferred from the buffer chamber 300 to the plasma process chamber 310 shown as an arrow 35. After an etching process in the plasma process chamber 310, the wafer is returned to the buffer chamber 300. Later, the wafer is transferred from the buffer chamber 300 to the deposition chamber 320 shown as an arrow 36. After the deposition is accomplished, the wafer is returned to the buffer chamber 300. The wafer is soon sent to the diffusion chamber 330 for annealing shown as an arrow 37. According to the present disclosure, chambers 310, 320 and 330 can also be configured to other different process.

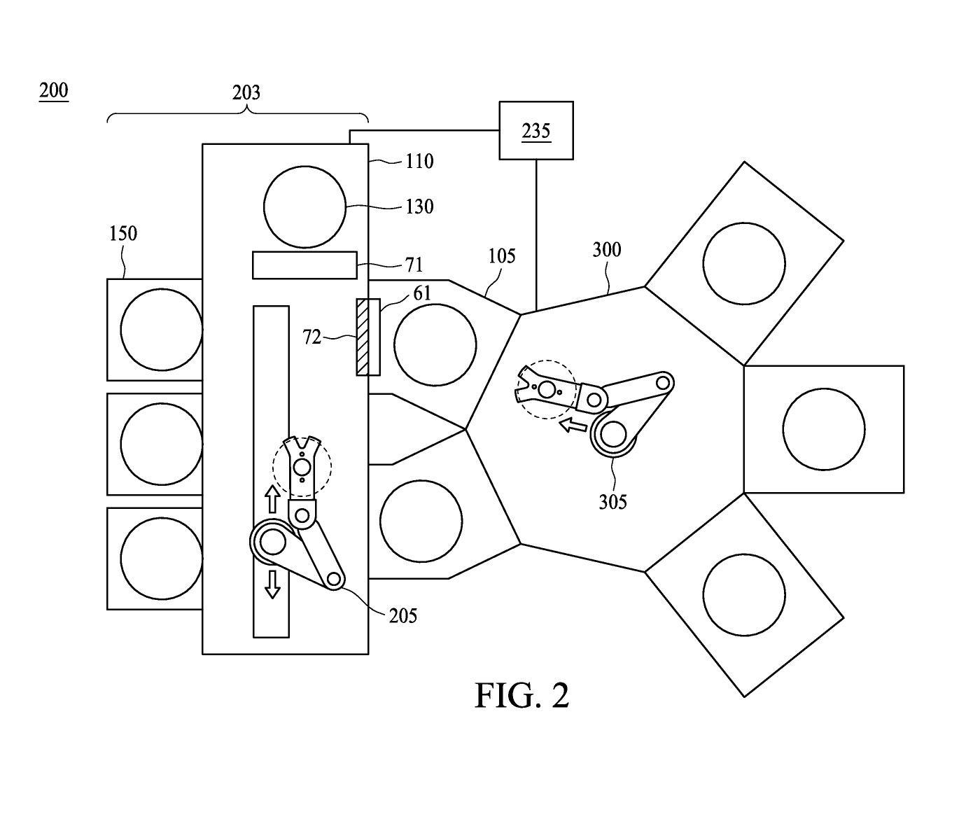

In order to deal with the particle issues, particle removers are equipped in the multi-chamber system 100. In reference to the figures, FIG. 2 is a top view illustrating a multi-chamber system 200 in accordance with some embodiments of the present disclosure. The multi-chamber system 200 includes a factory interface 203 and a buffer chamber 300. The factory interface 203 and the buffer chamber 300 are connected by load lock chamber 105. The multi-chamber system 200 has several process chambers disposed around the buffer chamber 300. The buffer chamber 300 is coupled to a vacuum system (not shown) so as to provide a reduced atmosphere condition. The factory interface 203 is similar to the factory interface 103 of FIG. 1, and the difference is that factory interface 203 further includes particle removers. In an embodiment, the factory interface 203 further includes a particle remover 71 adjacent to or above an orienter 130. The particle remover 71 faces toward wafers, wherein the particle remover 71 is configured to blow ionized gas on a surface of the wafer so as to remove particles. The particle remover 71 is designed to be equipped on a traveling path of wafers; for example, the particle remover 71 is above or beneath the traveling path of wafers. The particle remover 71 clean particles or objects on wafers before the wafers are transferred into process chambers. The particle remover 71 is a bar-shape box including gas inlets and gas outlets, which are referred to as gas knives. In some embodiments, the gas inlets and gas outlets are elongated slits, which are longer than a diameter of a wafer so that a whole area of a wafer is cleaned. Further, the particle remover 71 is equipped with an ionizer in order to ionize gas and blow the ionized gas through the gas outlets, wherein the ionized gas includes, for example, ionized air, ionized argon, ionized nitrogen, ionized helium or other ionized inert gas. The ionized gas is spouted out through the gas outlets onto the surface of the wafers. By performing the spouting of the ionized gas, the electrostatic particles will be neutralized and then removed. As the ionized gas neutralizes and blows up particles of the wafers, gas inlets of the particle remover 71 suck in and collect the particles so as to keep the factory interface 203 clean. Therefore, the wafers before or after adjusting orientations are gas showered and cleaned by the particle remover 71. After cleaning by the particle remover 71, the wafers are transferred into manufacturing chambers for etching or deposition. In an embodiment, another particle remover is located below the orienter 130 and facing toward wafers, wherein a gap between the two particle removers allows the robot to pass through. The particle remover 71 is vertically aligned with another particle remover so that two sides of the wafers are both cleaned and blown by the particle remover 71 and another particle remover.

In an embodiment, the factory interface 203 further includes a particle remover 72 around valve 61, which is located between load lock chamber 105 and the housing 110 of the factory interface 203. The particle remover 72 has a length of gas outlets that are longer than or equal to that of the valve 61. A structure of the particle remover 72 is the same as the particle remover 71. In an embodiment, another particle remover is located below and vertically aligned with the particle remover 72 around the valve 61, wherein the two particle removers are arranged in a face-to-face manner and toward wafers. The two particle removers are placed apart at a distance and allow the robot 205 to pass through so that two sides of the wafers are both cleaned and gas showered by the particle remover 72 and another particle remover. Therefore, the wafers before manufacturing processes are gas showered and cleaned by the particle remover 72. The particles are blocked and drawn out at the valve 61 so that the manufacturing chambers are kept clean.

The multi-chamber system 200 further includes a control unit 235 configured to communicate with the factory interface 203 or the buffer chamber 300 to allow various operations to be performed in a coordinated fashion. The control unit 235 includes a central processing unit (CPU), a memory, and a support circuit (not shown). The CPU is a general purpose computer processor used in an industrial setting. The CPU receives signals from end terminals and calculates the signals so as to send demands back to the end terminals for operations. The support circuit is coupled to the CPU and may include cache, clock circuits, input/output subsystems, power supplies, and the like. For example, the control unit 235 is able to manipulate movements of the robot 205. In addition, the particle removers (71, 72) are associated with the robot 205 through the control unit 235, wherein the particle removers (71, 72) are configured to manipulate a speed of the robot 205, a flow rate measured at the gas inlets and a flow rate measured at the gas outlets. In operation, the particle removers (71, 72) collect particles and analyze the quantity and sizes of particles entering the gas inlets. The information of the particles is transmitted to the control unit 235 so that the control unit 235 will judge the particle contamination of wafers and determine a speed of the robot 205, a flow rate measured at the gas inlet, and a flow rate measured at the gas outlet according to the quantity and sizes of the particles. If there are amounts of particles detected by the particle removers (71, 72), the control unit 235 will slow down the speed of the robot 205 during the removal of the particles so as to make a complete cleaning of the particles. If the speed of the robot 205 is slow when the particle removers (71, 72) are blowing, the wafers are comprehensively gas showered so that the cleaning effect or efficiency of the particles is enhanced. In some embodiments, if large amounts of particles are detected, a flow rate of the gas outlets are increased so as to enhance the quantity and strength of the ionized gas blowing on the wafers. Meanwhile, a flow rate of the gas inlets is also adjusted so as to remove more particles.

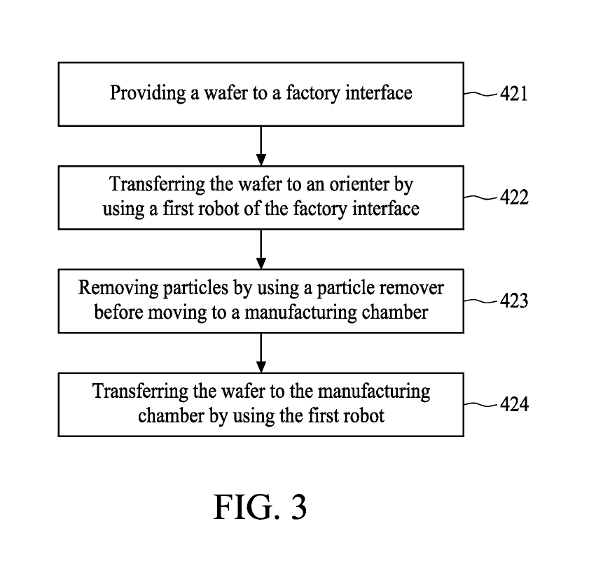

Based on the multi-chamber system 200, FIG. 3 shows a flow chart of a particle removing process in accordance with some embodiments of the present disclosure. The particle removing process is initiated at the step 421, providing a wafer to a factory interface 203. A cassette of wafers is loaded at a load port 150, in the step 422, and the wafers are transferred to an orienter 130 by using a first robot 205 of the factory interface 203. The first robot 205 handles the wafer and transfers the wafer to be placed on the orienter 130. Later, the orienter 130 starts to rotate and adjust an orientation of the wafer. After finding a correct alignment, in the step 423, particles are removed by using a particle remover 71 before moving to a manufacturing chamber. The particle remover 71 blows ionized gas on the wafer and sucks in particles bouncing from the wafer. After removing the particles, in the step 424, the wafer is transferred to the manufacturing chamber by using the first robot 205.

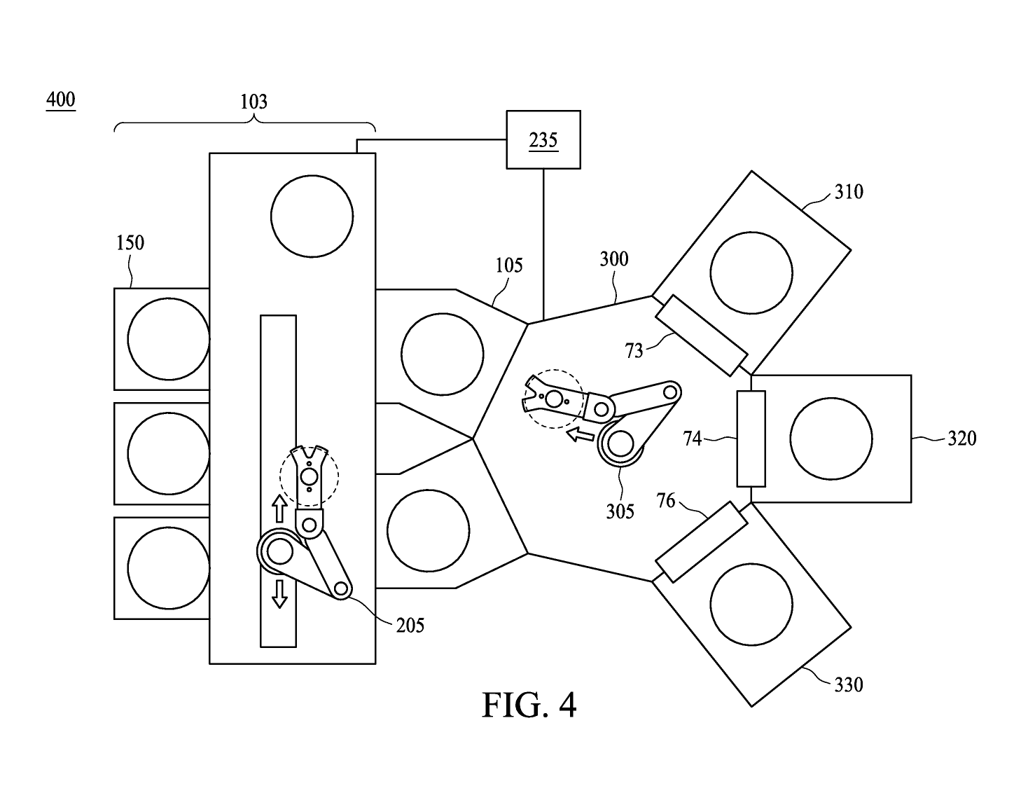

In another example, particle removers are equipped adjacent to manufacturing chambers. In reference to the figures, FIG. 4 is a top view illustrating a multi-chamber system 400 in accordance with some embodiments of the present disclosure. The multi-chamber system 400 includes a factory interface 103 and a buffer chamber 300. The multi-chamber system 400 is similar to the multi-chamber system 100 of FIG. 1, and the difference is that particle removers are equipped around valves between the buffer chamber 300 and manufacturing chambers. The multi-chamber system 400 has several process chambers disposed around the buffer chamber 300; for example, the buffer chamber 300 is coupled with a plasma process chamber 310, a deposition chamber 320 and a diffusion chamber 330. A particle remover 73 is equipped around a valve, which is located between the buffer chamber 300 and the plasma process chamber 310. A particle remover 74 is equipped around a valve, which is located between the buffer chamber 300 and the deposition chamber 320. Moreover, a particle remover 76 is equipped around a valve, which is located between the buffer chamber 300 and the diffusion chamber 330. The particle removers (73, 74, and 76) are above or below a traveling path of a wafer and facing toward the traveling path, wherein the particle removers (73, 74, and 76) are configured to blow ionized gas on a surface of the wafer and remove particles. Further, the particle removers (73, 74, and 76) are designed as a bar-shape box including several gas inlets and gas outlets. The gas inlets and gas outlets are elongated slits, which are also referred to as gas knives. The gas outlets provide an exit of ionized gas aimed at the wafers. The gas inlets are able to suck in particles bouncing from the wafers. In operation, a robot 305 handles a wafer and then transfers the wafer to a manufacturing chamber such as the plasma process chamber 310, the deposition chamber 320 and the diffusion chamber 330. The particle removers (73, 74, and 76) blow ionized gas on wafers and suck in the particles bouncing from the wafers. Further, the particle removers (73, 74, and 76) analyze the quantity and sizes of the particles in order to adjust a speed of a robot 305, a flow rate measured at the gas inlets and a flow rate measured at the gas outlets. The speed of the robot 305 is determined in accordance with the quantity and sizes of particles collected by the particle removers (73, 74, and 76) since the particle removers (73, 74, and 76) are associated with the robot 305 through a control unit 235. Therefore, before entering into the manufacturing chambers, particles on the wafer are removed by the particle removers (73, 74, and 76).

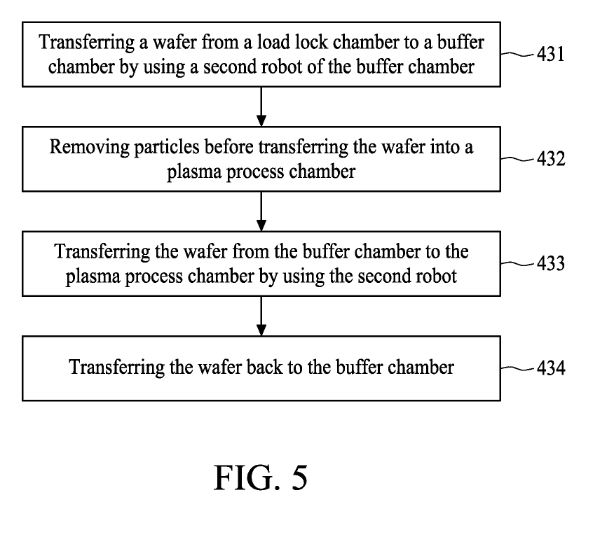

Based on the multi-chamber system 400, a possible process flow can be generalized as a flow chart. FIG. 5 shows a flow chart of a particle removing process in accordance with some embodiments of the present disclosure. The particle removing process is initiated at the step 431, moving a wafer from load lock chamber 105 to a buffer chamber 300 by using a second robot 305 of the buffer chamber 300. A valve between the buffer chamber 300 and the load lock chamber 105 is opened and allows the second robot 305 to handle the wafer. In the step 432, particles are removed before transferring the wafer into a plasma process chamber 310. The particle remover 73 cleans the wafer around a valve between the plasma process chamber 310 and the buffer chamber 300 while slowly moving into the plasma process chamber 310. Particles on the wafer are removed so that a partial etch or defects can be avoided. In the step 433, the wafer is transferred from the buffer chamber 300 to the plasma process chamber 310 by using the second robot 305. The plasma process chamber 310 is enclosed and performs an etching process. After the etching process is finished, in the step 434, the wafer is transferred back to the buffer chamber 300.

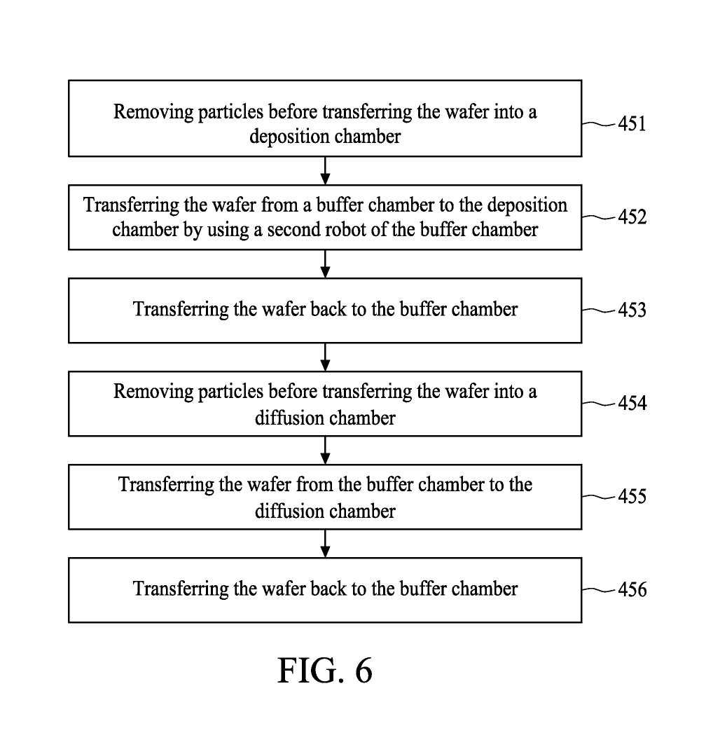

Based on the multi-chamber system 400, another possible process flow can be generalized as a flow chart. After the etching process, the wafer continues to be deposited or diffused. FIG. 6 shows a flow chart of a particle removing process in accordance with some embodiments of the present disclosure. In the step 451, particles are removed before transferring the wafer into a deposition chamber 320. The particle remover 74 cleans the wafer around a valve between the deposition chamber 320 and the buffer chamber 300 while slowly moving into the deposition chamber 320. After removing the particles on the wafer, in the step 452, the wafer is transferred from the buffer chamber 300 to the deposition chamber 320 by using the second robot 305 of the buffer chamber 300. A deposition is performed on the wafer in the deposition chamber 320. After the deposition, in the step 453, the wafer is transferred back to the buffer chamber 300. After the wafer is deposited with material layers, the wafer needs to anneal, in the step 454, whereby particles are removed before transferring the wafer into a diffusion chamber 330. Particles on the wafer are cleaned so as to prevent the particles from reacting with the material layers at a high temperature. In the step 455, the wafer is transferred from the buffer chamber 300 to the diffusion chamber 330. In the step 456, the wafer is transferred back to the buffer chamber 300.

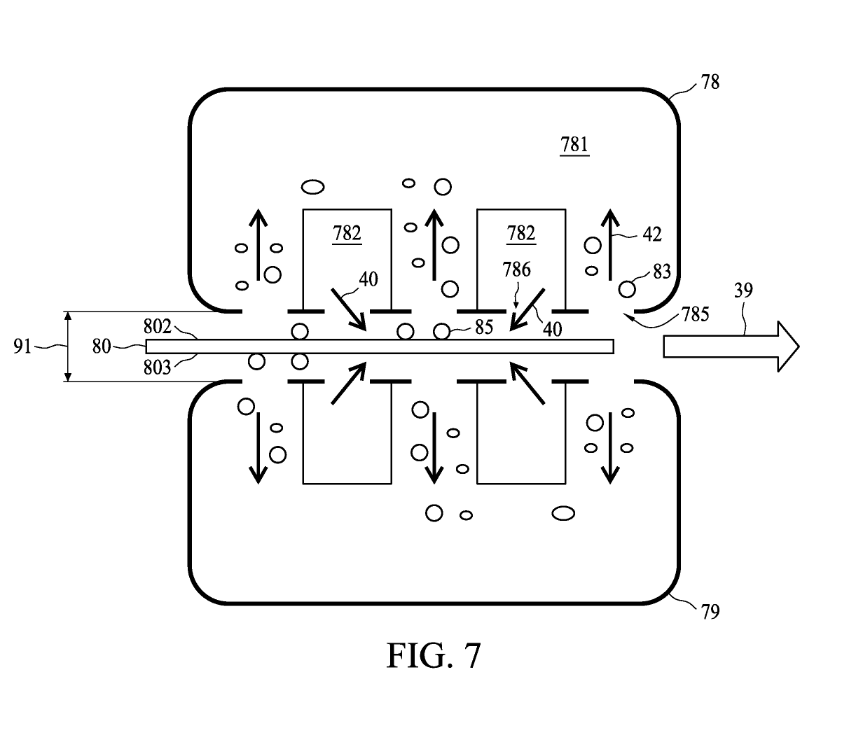

In some embodiments, the particle removers (71, 72, 73, 74, and 76) are respectively and vertically aligned with another particle remover as shown in FIG. 7. A particle remover 78 is arranged above a traveling path 39 of a wafer 80, whereas a particle remover 79 is located beneath the traveling path 39, wherein the particle remover 78 is vertically aligned with the particle remover 79. Since both of the particle removers (78, 79) are facing toward the traveling path 39, gas inlets and gas outlets of the particle removers (78, 79) aim at both surfaces of the wafer 80; for example, gas inlets 785 and gas outlets 786 facing the wafer 80. In addition, the two particle removers (78, 79) are placed apart at a distance 91 so as to form a gap between them where the distance 91 measured from the particle remover 78 to the particle remover 79 is about a few millimeters. Thus, the gas inlets 785 and gas outlets 786 of the particle remover 78 are proximal to the wafer 80, wherein a distance measuring from the gas inlets 785 and gas outlets 786 to the wafer 80 is about 1 to 2 millimeters. Further, the distance 91 allows robots to pass through so that two sides of the wafer 80 are both cleaned and gas showered by the particle remover 78 and 79. The distance 91 is short enough so as not to weaken the strength of the ionized gas exiting the gas outlets. Regarding the structures of the particle remover 78 which are the same as the particle remover 79, the particle remover 78 includes an intake chamber 781 and ion chambers 782. The intake chamber 781 surrounds the ion chambers 782, wherein the intake chamber 781 is isolated from the ion chambers 782. The intake chamber 781 has three gas inlets 785, whereas the ion chambers 782 respectively have two gas outlets 786. The intake chamber 781 is able to suck in gas since the intake chamber 781 is designed to be a negative pressure chamber including a pressure ranging about −1.5 to −20 Kpa or about −5 to −50 Kpa. The ion chambers 782 are equipped with an ionizer (not shown) so as to ionize the gas exiting the gas outlets 786. The ion chambers 782 are able to blow the ionized gas since the ion chambers 782 have positive pressures in a range from about 1.5 to 11 Kpa or about 2 to 30 Kpa. In an embodiment, the pressure of the intake chamber 781 is about −2 Kpa, whereas the pressure of the ion chambers 782 is about 2.5 kPa, which is found to have better efficiency for cleaning particles. In operation, the ion chambers 782 produce ionized gas and then pressurize the ionized gas blowing through the gas outlets 786. Due to inclining of the gas outlets 786, ejecting directions 40 of the gas outlets 786 are inclined with a predetermined angle so that the ionized gas obliquely sprays on the wafer 80. With the ejecting directions 40, particles 85 on the wafer 80 are subject to be detached or neutralized so that cleaning efficiency is improved. The intake directions 42 of the gas inlets 785 are orthogonal to the traveling path 39 so as to comprehensively suck in bouncing particles 83. Therefore, the wafers before manufacturing processes are gas showered and cleaned by the particle removers 78 and 79.

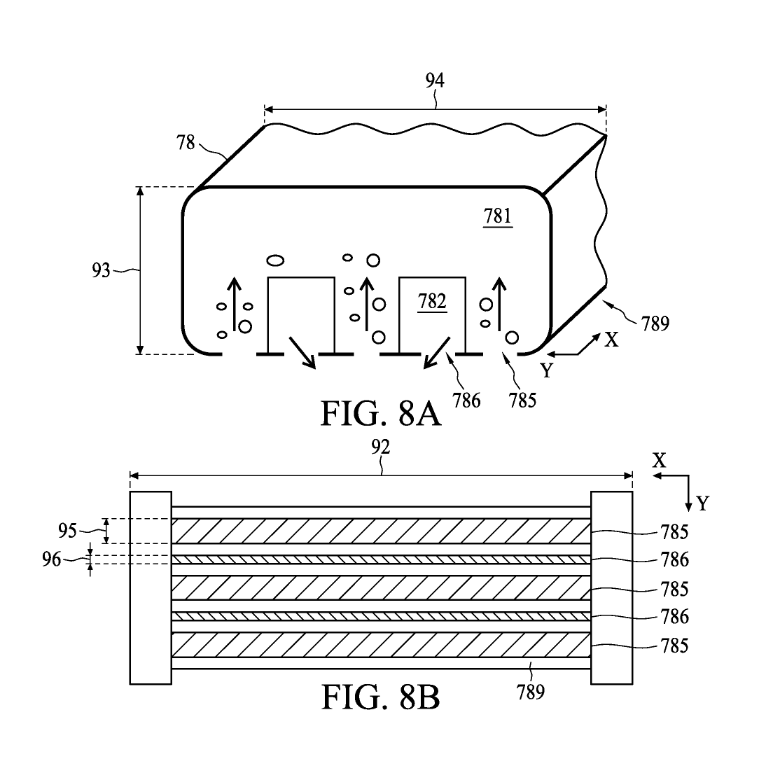

To clarify a configuration of gas inlets and gas outlets of the particle removers, FIG. 8A is a schematic diagram illustrating a cross-sectional view of the particle remover 78 in accordance with some embodiments of the present disclosure. The particle remover 78 is a cuboid or bar-shaped box including, for example, a height 93 of the particle remover 78 ranging from about 8 to 15 centimeters; and a depth 94 of the particle remover 78 ranging from about 10 to 20 centimeters. The particle remover 78 includes two gas outlets 785 and three gas inlets 786, wherein each gas outlet or gas inlet is extended along an X-direction. Further, the gas outlets 785 and gas inlets 786 are arranged one by one along a Y-direction on a bottom surface 789. Turning to FIG. 8B, FIG. 8B is a schematic diagram illustrating a bottom view of the particle remover 78. The particle remover 78 includes a length 92 longer than or equal to a diameter of a wafer, wherein the length 92 ranges from about 20 to 100 centimeters. Each gas inlet 786 is arranged parallelly with each gas outlet 785 along the Y-direction, and each gas outlet or gas inlet is extended along the X-direction. A distance measuring from one of the gas outlets 785 to an adjacent one of the gas inlets 786 is about 1 or 2 centimeters. Two of the gas inlets 786 are disposed at a periphery of the bottom surface 789. The gas outlets 785 and the gas inlets 786 are elongated slits, wherein a slit width of the gas outlets 785 is about 2 centimeters and a slit width of the gas inlets 786 is about 1 centimeter. By this configuration, the particle remover 78 can remove most of the particles on wafers and establish a clean environment for manufacturing processes. In an embodiment, the particle remover 78 includes at least two gas outlets and at least three gas inlets, wherein each gas inlet is arranged parallelly with each gas outlet. The at least two gas outlets and at least three gas inlets are all elongated slits, wherein slit widths of the gas outlets and gas inlets are the same and measured to be within a few centimeters. In an embodiment, the particle remover 78 includes a gas inlet and a gas outlet, wherein the gas inlet is parallelly arranged with the gas outlet.

To specify the operation of the particle remover 78, the ion chambers 782 produce ionized gas by an ionizer and pressurize the ionized gas. The ionized gas is made of ionized air or ionized non-active gas such as ionized argon, ionized helium, ionized nitrogen or other ionized inert gas. When the wafer 80 passes through the particle remover 78, particles adherent to the surfaces of the wafer 80 are blown away by ionized gas with high-pressure sprayed from the gas outlets 786. A direction of the ionized gas is inclined downwardly at a predetermined angle (θ), which can efficiently remove the particles. A particle is attached on the wafer 80 by, for example, gravity, molecular attraction, static electricity or moisture. The particles attached on the wafer 80 by gravity are easily blown off by the ionized gas. If the particles are attached on the wafer 80 by molecular attraction or static electricity, the ionized gas can neutralize or discharge the static electricity of the particles since the ionized gas has an amount of ionic charges. The particles thus are detached from the wafer 80 and sucked into the particle remover 78 through the gas inlets 786. In other cases, if the particles are attached on the wafer 80 by moisture, the ionized gas can dissipate the moisture and then remove the particles. As the particles are bouncing from the wafer 80, the particle remover 78 sucks in the particles through the gas inlets 786 so that the particles cannot attached onto the wafer 80 again. The particles are kept in the intake chamber 781 and monitored by the particle remover 78. The particle remover 78 extracts information of the particles such as the quantity and sizes of the particles. Later, the particle remover 78 will adjust a flow rate of the ionized gas or a flow rate of the sucking according to the quantity and sizes of the particles. Therefore, the particle remover 78 is able to remove the particles on a front side 802 or a back side 803 of the wafer 80. Since the particle remover 78 removes the particles of the front side 802, the wafer 80 is cleaned and ready for etching or deposition processes. By using the particle remover 78, a partial etch or defects will not occur at the front side 802 of the wafer 80. In addition, since the particle remover 78 removes the particles from the back side 803, helium will not leak from the gap between the wafer 80 and an electrostatic chuck (ESC), and by consequence a helium alarm will not be triggered.

In brief, the particle removers are equipped adjacent to an orienter or around valves so that wafers are comprehensively cleaned. Further, the particle removers blow ionized gas on wafers and neutralize particles on the wafer. Particles at a front side of a wafer are removed so as to avoid formation of defects or a partial etch, and particles at a back side of the wafer are removed so as not to trigger a helium alarm. The particles are sucked and collected in the particle removers so that a manufacturing chamber is kept clean from particle contamination. In addition, the particle removers have a structure where each gas inlet is parallelly arranged with each gas outlet. This configuration provides a better efficiency and cleaning effect.

An apparatus for processing a semiconductor wafer includes a factory interface configured to couple with a manufacturing chamber. The factory interface includes a robot; an orienter adjacent to the robot; and a particle remover above the orienter and facing toward a wafer. The particle remover is configured to blow ionized gas on a surface of the wafer in order to remove particles.

In some embodiments, the apparatus further includes a particle remover below the orienter and facing toward the wafer, wherein a gap between the two particle removers allows the robot to pass through.

In some embodiments, the manufacturing chamber includes a load lock chamber coupled with the factory interface. The factory interface further includes a particle remover around a valve located between the load lock chamber and the factory interface.

In some embodiments, the particle remover is associated with the robot. The particle remover is configured to manipulate a speed of the robot.

In some embodiments, the particle remover includes a gas outlet facing the surface of the wafer and applying gas on the surface; a gas inlet adjacent to the gas outlet; and an ionizer configured to ionize gas prior to exiting the gas outlet.

In some embodiments, the gas outlet and the gas inlet are elongated slits.

In some embodiments, the particle remover is configured to analyze quantity and sizes of the particles entering the gas inlet. The particle remover manipulates a speed of the robot, a flow rate measured at the gas inlet and a flow rate measured at the gas outlet according to the quantity and sizes of the particles.

In some embodiments, the particle remover includes at least two gas outlets facing the surface of the wafer and applying gas on the surface; at least three gas inlets; and an ionizer configured to ionize gas prior to exiting the at least two gas outlets. Each gas inlet is arranged parallelly with each gas outlet.

In some embodiments, the at least two gas outlets and the at least three gas inlets are elongated slits.

An apparatus for processing a semiconductor wafer includes a buffer chamber configured to couple with a manufacturing chamber. The buffer chamber includes a robot configured to transfer a wafer to the manufacturing chamber; and a particle remover above a traveling path of the wafer and facing toward the traveling path. The particle remover is configured to blow ionized gas on a surface of the wafer and remove particles.

In some embodiments, the apparatus further includes a particle remover beneath the traveling path and facing toward the traveling path, wherein the particle remover vertically aligns with the particle remover above the traveling path.

In some embodiments, the apparatus further includes a plasma process chamber coupled with the buffer chamber; and a particle remover around a valve, which is located between the buffer chamber and the plasma process chamber.

In some embodiments, the apparatus further includes a deposition chamber coupled with the buffer chamber; and a particle remover around a valve, which is located between the buffer chamber and the deposition chamber.

In some embodiments, the apparatus further includes a diffusion chamber coupled with the buffer chamber; and a particle remover around a valve, which is located between the buffer chamber and the diffusion chamber.

In some embodiments, the particle remover is associated with the robot, and the particle remover is configured to manipulate a speed of the robot in accordance with quantity and sizes of particles collected by the particle remover.

A method for processing a semiconductor wafer includes providing a wafer to a factory interface; transferring the wafer to an orienter by using a first robot of the factory interface; removing particles by using a particle remover before moving to a manufacturing chamber; and transferring the wafer to the manufacturing chamber by using the first robot.

In some embodiments, the step of removing the particles by using the particle remover further includes ionizing gas by using the particle remover; blowing the gas on the wafer and then detaching particles from the wafer; sucking the particles by using the particle remover; and monitoring quantity and sizes of the particles by using the particle remover.

In some embodiments, the method further includes adjusting a speed of the first robot according to the quantity and sizes of the particles monitored by the particle remover; adjusting a flow rate of the gas according to the quantity and sizes of the particles monitored by the particle remover; and adjusting a flow rate of the sucking according to the quantity and sizes of the particles monitored by the particle remover.

In some embodiments, the method further includes transferring the wafer from a load lock chamber to a buffer chamber by using a second robot of the buffer chamber; removing particles before transferring the wafer into a plasma process chamber; transferring the wafer from the buffer chamber to the plasma process chamber by using the second robot; and transferring the wafer back to the buffer chamber.

In some embodiments, the method further includes removing particles before transferring the wafer into a deposition chamber; transferring the wafer from a buffer chamber to the deposition chamber by using a second robot of the buffer chamber; transferring the wafer back to the buffer chamber; removing particles before transferring the wafer into a diffusion chamber; transferring the wafer from the buffer chamber to the diffusion chamber; and transferring the wafer back to the buffer chamber.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An apparatus for processing a semiconductor wafer, comprising:
a factory interface configured to couple with a manufacturing chamber, comprising:
a robot;
an orienter adjacent to the robot; and
a particle remover above the orienter and facing toward a wafer, wherein the particle remover is configured to blow ionized gas on a surface of the wafer so as to remove particles.

2. The apparatus of claim 1, further comprising a particle remover below the orienter and facing toward the wafer, wherein a gap between the two particle removers allows the robot to pass through.

3. The apparatus of claim 1, wherein the manufacturing chamber comprises a load lock chamber coupled with the factory interface, and the factory interface further comprises a particle remover around a valve located between the load lock chamber and the factory interface.

4. The apparatus of claim 1, wherein the particle remover is associated with the robot, and the particle remover is configured to manipulate a speed of the robot.

5. The apparatus of claim 1, wherein the particle remover comprises:
a gas outlet facing the surface of the wafer and applying gas on the surface;
a gas inlet adjacent to the gas outlet; and
an ionizer configured to ionize gas prior to exiting the gas outlet.

6. The apparatus of claim 5, wherein the gas outlet and the gas inlet are elongated slits.

7. The apparatus of claim 5, wherein the particle remover is configured to analyze quantity and sizes of the particles entering the gas inlet, and manipulate a speed of the robot, a flow rate measured at the gas inlet and a flow rate measured at the gas outlet according to the quantity and sizes of the particles.

8. The apparatus of claim 1, wherein the particle remover comprises:
at least two gas outlets facing the surface of the wafer and applying gas on the surface;
at least three gas inlets, wherein each gas inlet is arranged parallelly with each gas outlet; and
an ionizer configured to ionize gas prior to exiting the at least two gas outlets.

9. The apparatus of claim 8, wherein the at least two gas outlets and the at least three gas inlets are elongated slits.

10. An apparatus for processing a semiconductor wafer, comprising:
a buffer chamber configured to couple with a manufacturing chamber, comprising:
a robot configured to transfer a wafer to the manufacturing chamber; and
a particle remover above a traveling path of the wafer and facing toward the traveling path, wherein the particle remover is configured to blow ionized gas on a surface of the wafer and remove particles.

11. The apparatus of claim 10, further comprising:
a particle remover beneath the traveling path and facing toward the traveling path, wherein the particle remover vertically aligns with the particle remover above the traveling path.

12. The apparatus of claim 10, further comprising:
a plasma process chamber coupled with the buffer chamber; and
a particle remover around a valve, which is located between the buffer chamber and the plasma process chamber.

13. The apparatus of claim 10, further comprising:
a deposition chamber coupled with the buffer chamber; and
a particle remover around a valve, which is located between the buffer chamber and the deposition chamber.

14. The apparatus of claim 10, further comprising:
a diffusion chamber coupled with the buffer chamber; and
a particle remover around a valve, which is located between the buffer chamber and the diffusion chamber.

15. The apparatus of claim 10, wherein the particle remover is associated with the robot, and the particle remover is configured to manipulate a speed of the robot in accordance with quantity and sizes of particles collected by the particle remover.

16. A method for processing a semiconductor wafer, comprising:
providing a wafer to a factory interface;
transferring the wafer to an orienter by using a first robot of the factory interface;
removing particles by using a particle remover before moving to a manufacturing chamber; and
transferring the wafer to the manufacturing chamber by using the first robot.

17. The method of claim 16, wherein the step of removing the particles by using the particle remover further comprises:
ionizing gas by using the particle remover;
blowing the gas on the wafer and then detaching particles from the wafer;
sucking the particles by using the particle remover; and
monitoring quantity and sizes of the particles by using the particle remover.

18. The method of claim 17, further comprising:
adjusting a speed of the first robot according to the quantity and sizes of the particles monitored by the particle remover;
adjusting a flow rate of the gas according to the quantity and sizes of the particles monitored by the particle remover; and
adjusting a flow rate of the sucking according to the quantity and sizes of the particles monitored by the particle remover.

19. The method of claim 16, further comprising:
transferring the wafer from a load lock chamber to a buffer chamber by using a second robot of the buffer chamber;
removing particles before transferring the wafer into a plasma process chamber;
transferring the wafer from the buffer chamber to the plasma process chamber by using the second robot; and
transferring the wafer back to the buffer chamber.

20. The method of claim 16, further comprising:
removing particles before transferring the wafer into a deposition chamber;
transferring the wafer from a buffer chamber to the deposition chamber by using a second robot of the buffer chamber;
transferring the wafer back to the buffer chamber;
removing particles before transferring the wafer into a diffusion chamber;
transferring the wafer from the buffer chamber to the diffusion chamber; and
transferring the wafer back to the buffer chamber.
